(19) United States
(12) Patent Application Publication
(10) Pub. No.: US 2011/0233732 A1
(43) Pub. Date: Sep. 29, 2011

(54) SUBSTRATE FOR AN ELECTRONIC OR ELECTROMECHANICAL COMPONENT AND NANO-ELEMENTS

(75) Inventors: Thomas Goislard De Monsabert, Beacon, NY (US); Chrystel Deguet, Saint Ismier (FR); Jean Dijon, Champagnier (FR); Marek Kostrzewa, Grenoble (FR)

(73) Assignee: COMMISSARIAT A L'ENERGIE ATOMIQUE ET AUX ENE ALT, Paris (FR)

(21) Appl. No.: 13/059,651

(22) PCT Filed: Aug. 31, 2009
(86) PCT No.: PCT/EP2009/061203

§ 371 Date: Jun. 7, 2011

(30) Foreign Application Priority Data
Sep. 1, 2008 (FR) 08 55852

(51) Int. Cl. H01L 29/06; H01L 29/02; H01L 21/762

(52) U.S. Cl. 257/618; 257/629; 438/458; 257/E29.002; 257/E29.005; 257/E21.568

(57) ABSTRACT

A substrate configured to support at least one electronic or electromechanical component and one or more nano-elements, formed with a base support, with a catalytic system, with a barrier layer, and with a layer configured to receive the electronic or electromechanical component, in single-crystal Si or in Ge or in a mixture of these materials. The catalytic system lies on the base support without any contact with the layer configured to receive electronic or electromechanical component and the barrier layer is sandwiched between the catalytic system and the layer configured to receive the electronic or electromechanical component. This barrier layer is without any contact with the base support.

### TECHNICAL FIELD

The present invention relates to electronic or electromechanical devices with nano-elements. More particularly, it proposes a substrate for at least one electronic or electromechanical component and one or more nano-elements, this substrate being a multilayer structure.

### STATE OF THE PRIOR ART

Nano-elements are for example used in the manufacturing of electronic devices. They are generally obtained by CVD (“chemical vapor deposition”) catalytic growth. Their electronic and/or electromechanical properties notably allow the building of highly performing electronic or electromechanical devices, such as CMOS transistors, interconnections or actuators.

In the prior art, multilayer structures allowing growth of nano-elements are known. They are generally formed with a base support which may be in a semiconducting material, for example single-crystal silicon, covered with a catalytic layer or with a stack of layers, at least one of which is catalytic, generally based on metals, from which the nano-elements, generally in silicon or in carbon will grow. Subsequently, “catalytic system” will designate the catalytic layer or the stack of layers, at least one of which is catalytic for growing nano-elements.

Such a structure is included in the description of document US 2007/0045691A, it is illustrated in FIG. 1. It is formed with an insulating layer 102 in silicon oxide (SiO₂), lying on a base support 101 in silicon and with a catalytic system 103 overlying the oxide layer 102. This catalytic system 103 allows the growth of nano-elements 104, in this case nanotubes. In order to separate the groups of nano-elements 104 from each other, insulating elements 105 which delimit boxes 107 are formed. Each group of nano-elements is found in a box. These insulating elements 105 are used as a support for a multilayer electrode 106. This electrode 106 is that of a remote electronic component such as a memory device (not shown), generally made in an area of the substrate 101, juxtaposed to the area described in FIG. 1: both of these areas are electrically connected through the electrode 106.

This structure has the major drawback of not positioning the nano-elements and the electronic components in close proximity to each other, which generates compactness problems and thereby problems of parasitic connection capacitances and resistors. But if the catalytic system and the electronic component were positioned in close proximity, they would be able to interact and deteriorate each other or else the catalytic system would be able to perturb the operation of the electronic component.

### DISCUSSION OF THE INVENTION

The object of the present invention is to manufacture a substrate allowing the growth of one or more nano-elements and the setting into place of at least one electronic or electromechanical component, which does not have the drawbacks of the prior art, i.e. notably, the risk of interaction between the catalytic material and the electronic or electromechanical component which may lead to their mutual deterioration. Indeed, a risk is that the catalytic system may be degraded, because of physical and chemical treatments which the structure undergoes during the steps for manufacturing the component. Now, for performing growth of nano-elements, this catalytic system should be of good quality. The stresses exerted on the structure during the manufacturing process should not alter it. Another risk originates from the fact that the catalytic devices are generally contaminants for the electronic or electromechanical components, notably transistors on silicon, which risks perturbing their operation.

An object of the invention is therefore to propose a substrate intended to support at least one electronic or electromechanical component and one or more nano-elements and which includes a catalytic system in which the catalytic system does not risk interacting with the component while playing its role in an optimum way during the growth of the nano-elements.

Another object of the invention is to propose a substrate intended to support at least one electronic or electromechanical component and one or more nano-elements, in which the nano-elements may be accessible.

In order to attain these performance goals, the present invention proposes a substrate intended to support at least one electronic or electromechanical component and one or more nano-elements, formed with a base support, a catalytic system for growing nano-elements comprising at least one catalytic layer, with a barrier layer, and with a layer capable of receiving the electronic or electromechanical component. The catalytic system lies on the base support without any contact with the layer capable of receiving the electronic or electromechanical component and the barrier layer is sandwiched between the catalytic system and the layer capable of receiving the electronic or electromechanical component so as to avoid interaction between the catalytic layer and the electronic or electromechanical component, this barrier layer being without any contact with the base support. The layer capable of receiving the electronic or electromechanical component is in single-crystal Si or in Ge or in a mixture of these materials.

The catalytic system may be formed with one or two groups of layers, each group including at least one catalytic layer. At least one of the groups may further include a protective layer on the catalytic layer and/or a supporting layer under the catalytic layer. It is possible that when the catalytic system includes two groups of layers, the supporting layer is common to both groups.

Alternatively, the catalytic system may be formed with a catalytic layer sandwiched between two supporting layers, both supporting layers being optionally sandwiched between two protective layers.

The catalytic layer may be made on the basis of iron, nickel, cobalt, these elements being taken alone or as an alloy.

The protective layer and the supporting layer may be made in a material selected from Al₂O₃, SiN, SiC, SiON, TiN, TiO₂, or TaN.

The base support, the barrier layer and/or the layer capable of receiving the electronic or electromechanical component may be multilayers.

The present invention also proposes an electronic or electromechanical device including at least one structure comprising a thereby characterized substrate. The structure further comprises at least one electronic or electromechanical component positioned on or in the layer capable of receiving the electronic or electromechanical component, at least one box dug into the substrate locally exposing the catalytic system on which one or more nano-elements are supported.

The box may have flanks which transversely interrupt the barrier layer showing a section of the barrier layer, each section contributing to forming the flanks of the box.

It is possible that the locally exposed catalytic system forms a bottom of the box.

The structure may further comprise at least one contact device housed in another box dug in the substrate, the box of the nano-elements and the box of the contact device each having a bottom, the box of the nano-elements and the box of the contact device being opposite through their bottoms.

The electronic or electromechanical device may include several structures stacked on each other.

The present invention also relates to a method for manufacturing a thereby characterized substrate, in which:
the catalytic system is formed on the base support;
the barrier layer is formed on the catalytic system;
the layer capable of receiving the electronic or electromechanical component in single-crystal Si or Ge or in a mixture of these materials is formed on the barrier layer.

The barrier layer and the layer capable of receiving the electronic or electromechanical component may be formed from:
a first adhesive bonding layer covering the base support itself covered with the catalytic system, the first adhesive bonding layer overlying the catalytic system or being a surface layer of the catalytic system on the one hand,
and a second adhesive bonding layer covering an auxiliary semiconducting substrate, this substrate having undergone ion implantation for embrittling it at a plane located at a certain distance from the interface between the substrate and the second adhesive bonding layer on the other hand,
by assembling the base support and the auxiliary semiconducting substrate by molecular adhesion of their adhesive bonding layers, their adhesive bonding layers assembled together providing the barrier layer,
and then by carrying out heat fracture of the auxiliary semiconducting substrate at the ion implantation, a layer of the auxiliary semiconducting substrate remaining adhesively bonded to the barrier layer following this fracture, providing the layer capable of receiving the electronic or electromechanical component.

Alternatively, the barrier layer and the layer capable of receiving the electronic or electromechanical component may be formed from
a first adhesive bonding layer covering the base support, itself covered with the catalytic system, the first adhesive bonding layer overlying the catalytic system or being a surface layer of the catalytic system on the one hand,
and a second adhesive bonding layer covering a substrate of the SOI type, having an electrically insulating layer sandwiched between two semiconducting layers of different thicknesses, the second adhesive bonding layer covering the less thick semiconducting layer on the other hand,
by assembling the base support and the substrate of the SOI type by molecular adhesion of their adhesive bonding layers, their adhesive bonding layers assembled together providing the barrier layer,
and then by removing the thickest semiconducting layer and the electrically insulated layer of the substrate of the SOI type, the less thick semiconducting layer of the substrate of the SOI type providing the layer capable of receiving the electronic or electromechanical component.

### SHORT DESCRIPTION OF THE DRAWINGS

The present invention will be better understood upon reading the description of given exemplary embodiments, purely as an indication and by no means as a limitation, with reference to the appended drawings, wherein:

FIG. 1, already described, is a multilayer structure known from the prior art;

FIG. 2 illustrates a substrate according to the invention;

FIGS. 3A-3E illustrate different catalytic systems used in the substrate of the invention;

FIGS. 4A-4D illustrate different steps of a first method for manufacturing a substrate according to the invention using Smart Cut™ technology;

FIGS. 5A-5D illustrate different steps of a second method for manufacturing a substrate according to the invention;

FIGS. 6A-6F illustrate an example of a method for manufacturing an electronic or electromechanical device according to the invention;

FIGS. 7A-7D illustrate another example of a method for making an electronic or electromechanical device according to the invention.

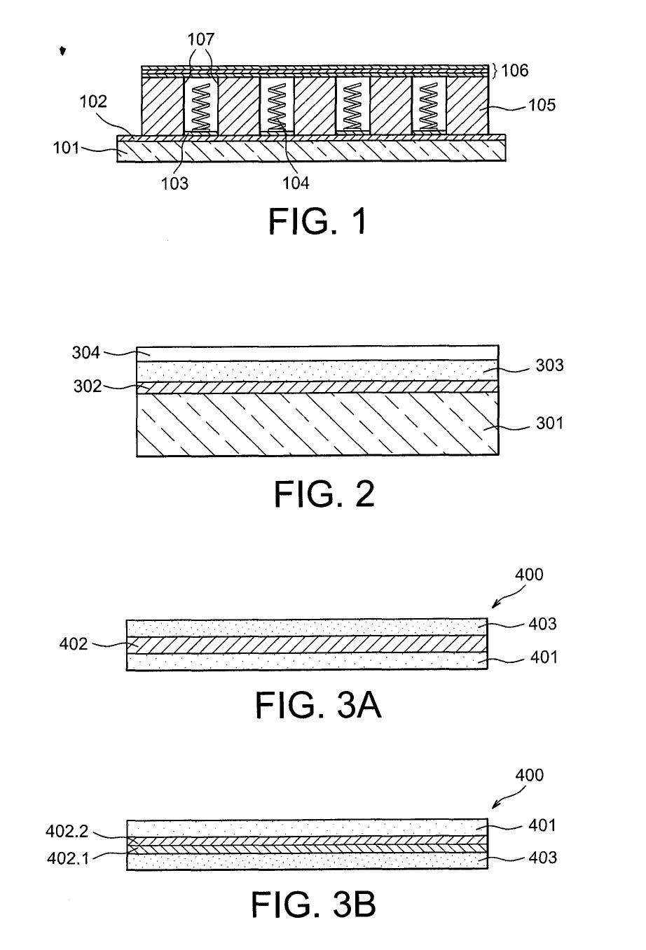

### DETAILED DISCUSSION OF PARTICULAR EMBODIMENTS

FIG. 2 illustrates a substrate according to the invention. It is formed by a stack from a base support 301. This base support 301 is preferably in semiconducting material. It may for example be in single-crystal silicon, in germanium or in a mixture of these materials. On this base support 301 lies a catalytic system 302 for the growth of one or more nano-elements comprising at least one catalytic layer. This catalytic system is generally formed with one or more groups of layers. The nano-elements may for example be carbon nanotubes, nanowires, nanofibers etc. On this catalytic system lies a barrier layer 303. This barrier layer 303 is generally formed with silicon oxide or a metal oxide, such as for example aluminum oxide. It is this barrier layer 303 which, by its position in the stack, insulates the catalytic system 302, from an electronic or electromechanical component, not shown, which will be made on and/or in a surface layer 304 capable of receiving it. The barrier layer avoids interaction between the catalytic layer and the electronic or electromechanical component. This layer 304 is for example in single-crystal silicon, in germanium or in a mixture of these materials. This layer 304 capable of receiving the electronic or electromechanical component covers the barrier layer 303. This substrate may for example be of the SOI (Semiconductor On Insulator) type. The component not shown may be both an electronic component and an electromechanical component.

More particularly, this substrate may form a substrate with a buried ground plane. In this case, the catalytic system forms the ground plane, if it has sufficient electric conduction conditions, in addition to its catalytic properties. These substrates, with a buried ground plane, have an advantage as regards substrates conventionally used, since they allow easier activation of the electronic components which they receive. Indeed, in these substrates, the applied electric fields remain confined above the ground plane. With the nano-elements, it is then possible make a contact on the catalytic system which plays the role of a ground plane.

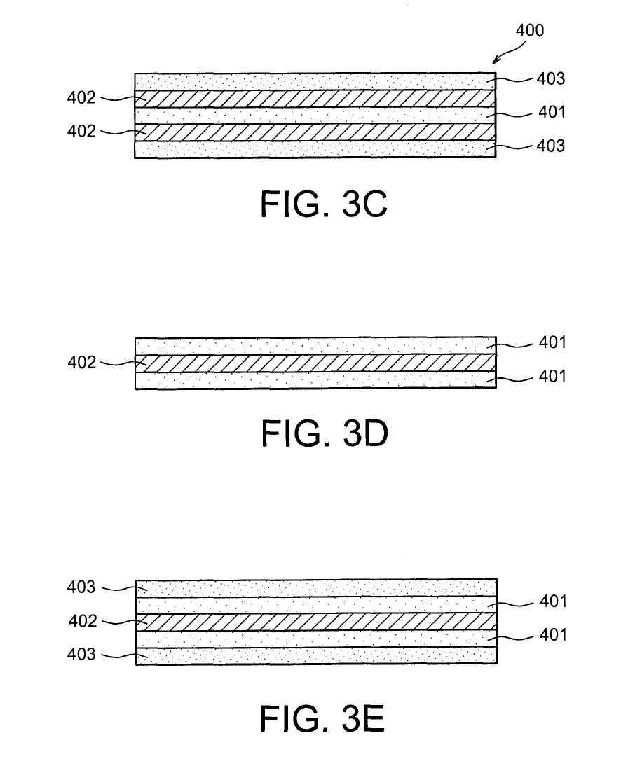

FIG. 3A shows an example of a catalytic system 400 which may be used in the substrate of the invention. It only includes a single group of stacked layers, each of these layers may itself be formed with a plurality of sub-layers. The group of layers includes at least one catalytic layer 402. More specifically, in this example it is formed with a supporting layer 401, on which lies the catalytic layer 402 for growing nano-elements, and with a protective layer 403 overlying the catalytic layer 402. This protective layer 403 has to be removed locally in order to allow nano-elements to be grown from the exposed catalytic layer 402. The protective layer 403 and the supporting layer 401 have the role of effectively confining the catalytic layer 402. The supporting layer 401 is for example formed with at least one element selected from: Al₂O₃, SiN, SiC, SiON, TiN, TiO₂, TaN. Its thickness may be comprised between about 1 nm and 100 nm. It is sought with the supporting layer 401 and the catalytic layer 402 to enable effective growth of the nano-elements. The catalytic layer 402 may be made on the basis of Fe, Ni or Co, these elements being taken alone or as an alloy. This catalytic layer 402 has a thickness which may be comprised about 0.1 nm and 10 nm. It is possible that the catalytic layer 402 is a multilayer, such as a bilayer as illustrated in FIG. 3B. The protective layer 403 is such that it is possible to remove it by etching without damaging the catalytic layer 402 during the use of the substrate. It is for example formed with a material selected from: Al₂O₃, SiN, SiC, SiON, TiN, TiO₂, or TaN. Its thickness may range from 1 to 100 nm for example. It is sought that the protective layer 403 and the supporting layer 401 be chemically and thermally stable during all the steps for manufacturing the substrate as well as during its use.

FIG. 3B shows an alternative of the catalytic system of FIG. 3A. It has been turned upside down relatively to the one of FIG. 3A, which allowed the nano-elements to grow downwards. Further, the catalytic layer 402 is a bilayer formed with a first sub-layer 402.1 as described earlier and with a second sub-layer 402.2 of interest for the growth and use of the nano-elements. The second sub-layer 402.2 may for example be formed with silicon and have a thickness comprised between about 1 and 10 nm. The first sub-layer 402.1 is found on the side of the protective layer 403 and may for example be formed with iron and have a thickness comprised between about 0.1 and 1 nm.

FIG. 3C illustrates a third embodiment of the catalytic system 400. This catalytic system has two groups of layers as described in FIG. 3A, placed side by side and stacked in the reverse order. The growth of the nano-elements may be accomplished on one side, on the other side or on both sides of the catalytic system depending on the catalytic layer(s) which will have been exposed. Groups of layers are placed side by side through their supporting layers 401. But now, both supporting layers only form a single layer.

FIG. 3D further illustrates another simplified embodiment of the catalytic device of nano-elements. It now includes a single catalytic layer 402 sandwiched between both supporting layers 401. Optionally, both supporting layers 401 may be sandwiched between two protective layers 403 as illustrated in FIG. 3E. Both of these latter configurations also allow growth of nano-elements on one side, on the other side or on both sides of the catalytic system.

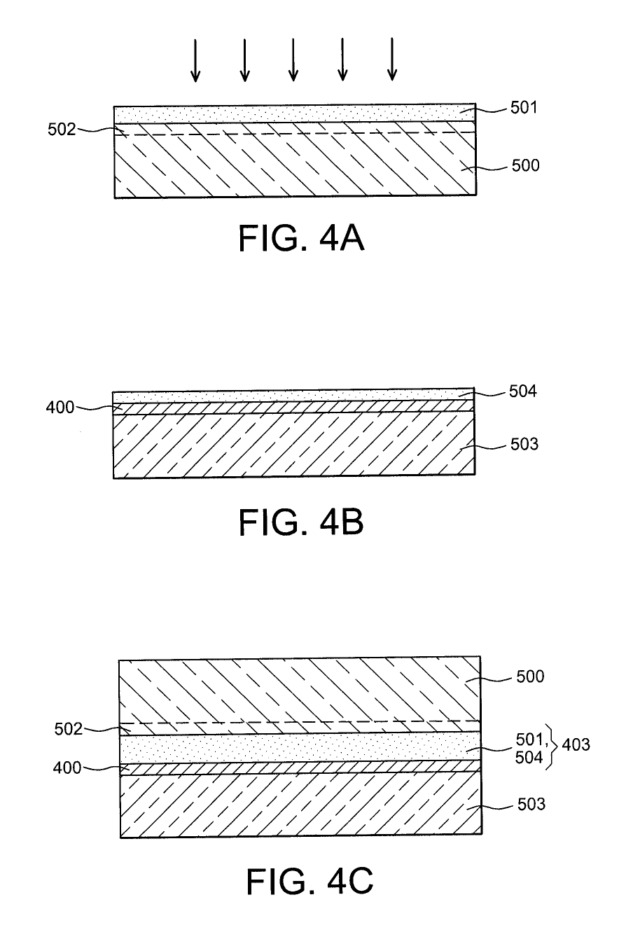

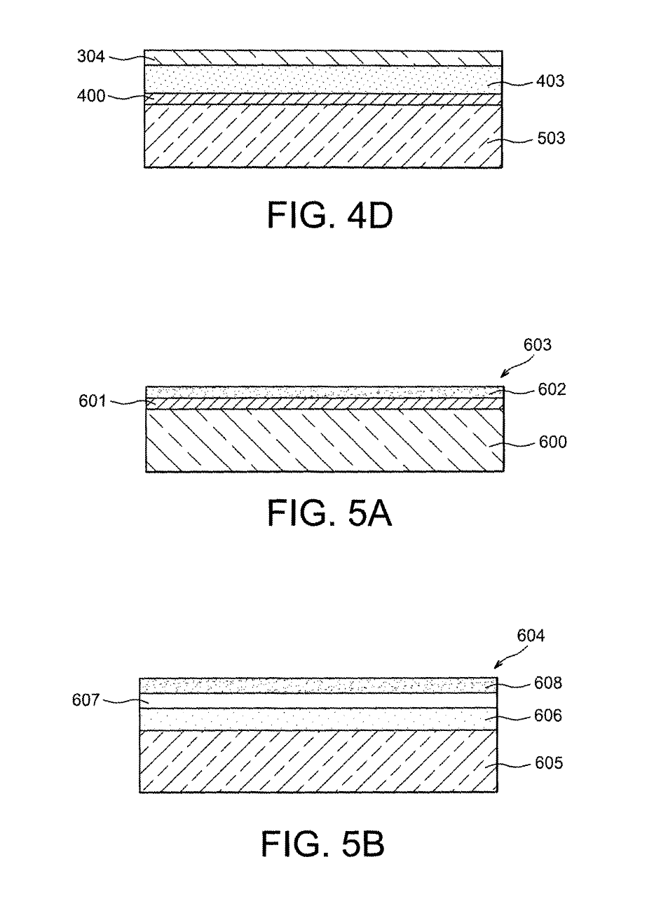

The present invention also proposes a method for manufacturing the substrate of the invention. FIGS. 4A-4D illustrate a first exemplary embodiment of this method using Smart Cut™, technology, for example as described in document U.S. Pat. No. 6,372,609 B1. From an auxiliary support 500, in bulk single-crystal silicon for example, a so-called adhesive bonding layer 501 in oxide is made on one of its faces. This adhesive bonding layer 501 may be in thermal oxide or else a layer of deposited oxide. It is this adhesive bonding layer 501, which will subsequently form partly the barrier layer 403. Ion implantation for example of hydrogen is carried out. (FIG. 4A). This generates an embrittled layer 502 localized in depth in the auxiliary support 500 under the adhesive bonding layer 501. It is formed with micro-cavities (not shown) which will allow fracture in a subsequent step.

In another step illustrated in FIG. 4B, a catalytic system 400 as described earlier is made on a base support 503, in single-crystal silicon. An adhesive bonding layer 504 as described in FIG. 4A may be formed on the catalytic system 400. If the adhesive bonding layer 504 is not made, the protective layer 403 of the catalytic system 400 may be used as an adhesive bonding layer for molecular adhesion, if its material is suitable. This alternative is not illustrated.

In another step illustrated in FIG. 4C, the adhesive bonding by molecular adhesion is carried out between both structures built during the two previous steps and illustrated in FIGS. 4A, 4B. The adhesive bonding is carried out between both adhesive bonding layers 501, 504 or between the adhesive bonding layer 501 and the protective layer 403 which are put into contact. In order to improve the quality of the adhesive bond, it is possible to treat the surfaces beforehand which will be put into contact. This may be chemical treatment or mechano-chemical polishing and/or surface treatment of the plasma type for example.

In another step, a so-called fracture step, the structure of FIG. 4C is exposed to a heat treatment of the order of 250° C. to 600° C. in order to split it into two at the embrittled area 502. Two portions are then obtained, the first is a reusable singe-crystal silicon element. The second portion is the substrate according to the invention. It is illustrated in FIG. 4D. It is formed with the base support in single-crystal silicon 503, covered with the catalytic system 400, and then with the barrier layer 403, and then with a fine surface layer of single-crystal silicon 304. By “fine layer”, is meant that the layer is less thick than the base support 503. This fine surface layer 304 is the layer capable of receiving the electronic or electromechanical component.

It is possible to carry out a treatment of this fine layer 304, in order to ensure good surface condition, and to give it a determined thickness. For example it consists of carrying out high temperature annealing in order to consolidate the adhesive bonding interface on the one hand, and of carrying out polishing of this fine layer in order to adjust its final thickness on the other hand.

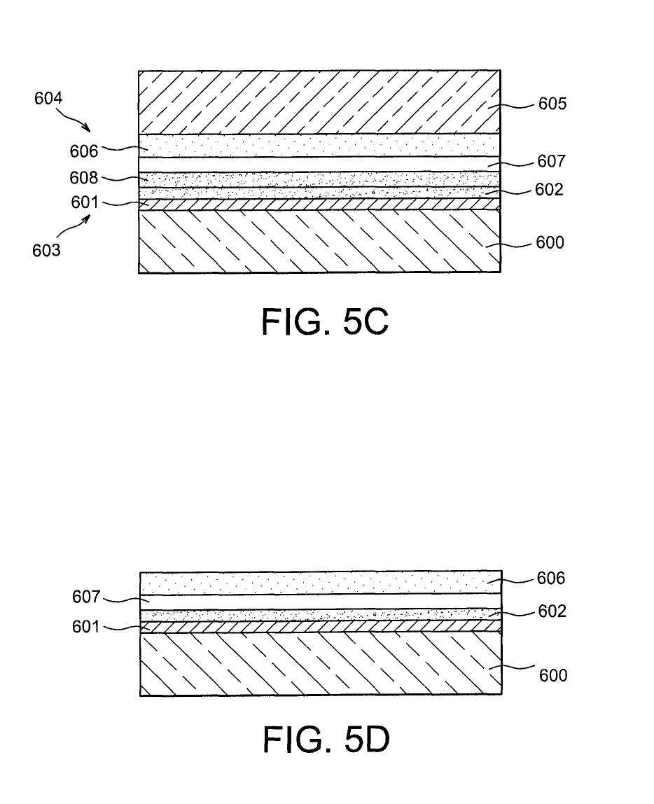

The present invention proposes a second example of a method for manufacturing a substrate according to the invention. FIGS. 5A-5D illustrate this method. FIG. 5A shows a first stack of layers 603 formed with a base support 600, in bulk single-crystal silicon for example, on which lays a catalytic system 601, as described earlier, covered with an adhesive bonding layer 602 which may be in silicon oxide for example. It is possible to do without the adhesive bonding layer 602 as this was seen earlier. In this case, the protective layer of the catalytic system 601 may replace it, if its material is suitable for molecular adhesion.

FIG. 5B shows another stack which is a substrate of the SOI type 604 covered with an adhesive bonding layer 608, in silicon oxide for example. The substrate of the SOI type 604 includes an electrically insulating layer 606, for example of silicon oxide, sandwiched between two semiconducting layers 607, 605. One of the semiconducting layers 605 is thicker than the other one, referenced as 607. The semiconducting layers may be in single-crystal silicon. The adhesive bonding layer 608 covers the thinnest semiconducting layer 607. Both adhesive bonding layers are not absolutely necessary, nevertheless one of the two stacks 603 or 604 should have an adhesive bonding layer as a surface layer.

In FIG. 5C, the two stacks obtained earlier are assembled by molecular adhesion between the adhesive bonding layer 602 of the first stack 603 and the adhesive bonding layer 608 of the second stack 604, if both stacks each have an adhesive bonding layer. A stack is obtained as illustrated in FIG. 5C. It consists of a succession of layers from the base support 600, i.e. in this order: the catalytic system 601, the adhesive bonding layer 602 of the first stack, the adhesive bonding layer 608 surmounting the SOI substrate 604, the thinnest semiconducting layer 607 of the SOI substrate 604, the electrically insulating layer 606 of the SOI substrate 604, the thickest semiconducting layer 605 of the SOI substrate.

If the SOI substrate 604 is not provided with an adhesive bonding layer, the assembling is carried out by molecular adhesion between the adhesive bonding layer 602 of the first stack 603 and the thinnest semiconducting layer 607 of the SOI substrate 604.

If the first stack 603 does not have any adhesive bonding layer, the assembling is carried out by molecular adhesion between the adhesive bonding layer 606 with which the SOI substrate 604 is equipped and the catalytic system 601 of the first stack 603.

Next, in another step, the thickest semiconducting layer 605 of the SOI substrate 604 will be removed, by mechanical grinding, and then by chemical etching. It is the electrically insulated layer 606 which is used as an etching stop layer. A stack is obtained as illustrated in FIG. 5D, comprising from the base support 600 in this order: the catalytic system 601, the adhesive bonding layer(s) 602, the thinnest semiconducting layer 607 of the SOI substrate 604 and the electrically insulating layer 606 of the SOI substrate 604.

The electrically insulating layer 606 of the SOI substrate 604 is removed by wet and/or dry etching. A stack is obtained in the first embodiment, and illustrated in FIG. 4D.

An electronic or electromechanical device will now be described provided with one or more nano-elements according to the invention and a method for making the device from the thereby described substrate.

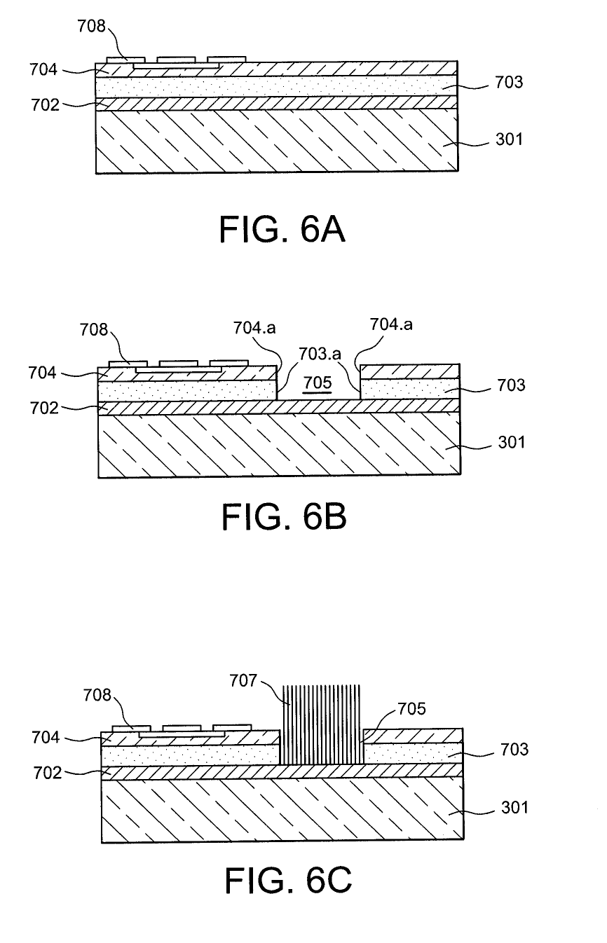

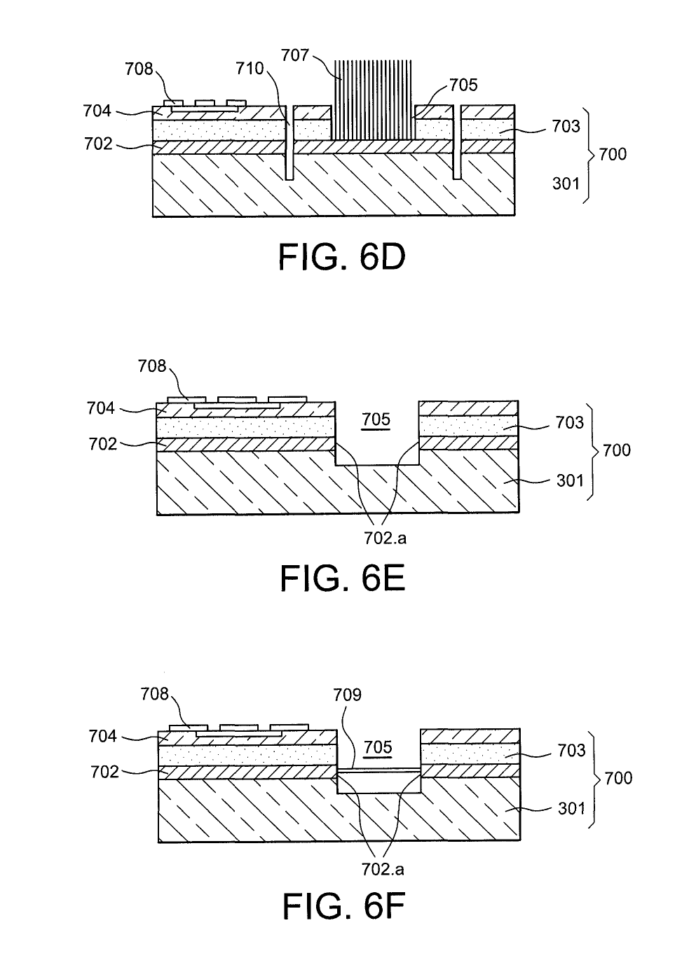

FIGS. 6A-6D illustrate this method. FIG. 6A shows a substrate 700 according to the invention provided with at least one electronic or electromechanical component 708 made on and in the layer capable of receiving the electronic or electromechanical component 704. It is formed with a stack of layers within this order, the base support in semiconducting material 301, the catalytic system 702, the barrier layer 703, and finally the layer 704 capable of receiving the electronic or electromechanical component 708 on and in which is made the electronic or electromechanical component. At least one box 705 is dug in the substrate from the layer capable of receiving the electronic or electromechanical component 704. This box 705 has a bottom which locally exposes the catalytic system 703. The box 705 is obtained for example by dry etching of the reactive plasma type. With etching, it is possible to uncover the layer capable of receiving the electronic or electromechanical component 704, and the barrier layer 703 as illustrated in FIG. 6B. The etching should not deteriorate the electronic or electromechanical component 708. It will be seen later on that the box may be dug from the base substrate.

The box 705 includes flanks. The barrier layer 703 is transversely interrupted and has an exposed section 703a which contributes to forming the flanks of the box 705. The same applies for the layer capable of receiving the electronic or electromechanical component 704. The section of the layer capable of receiving the electronic or electromechanical component 704 is referenced as 704a.

In another step illustrated in FIG. 6C, growth of one or more nano-elements 707, for example carbon nano-tubes, is effected in the box 705. The growth may be thermal CVD growth, from a carbonaceous gas. For this, the substrate 700 is heated to a temperature comprised between about 400° C. and 900° C. This increase in temperature has the effect of structuring the catalytic system 702, for example in the form of nanoparticles. The substrate 700 is then put into contact with a carbonaceous gas such as for example C₂H₂, CH₄, CH₃COOH or CO, which may optionally be mixed with other gases such as for example NH₃, H₂, H₂O in vapor form, He or N₂. The carbonaceous gas then decomposes upon contact with the catalytic system 702 giving rise to a deposit of solid carbon on this locally exposed catalytic system 702. For well selected experimental conditions such as for example a temperature of 700° C., a catalytic layer based on iron with a thickness of 1 nm, a supporting layer based on alumina with a thickness of 20 nm, a pressure of the order of 1 hPa, a gas mixture including C₂H₂, the solid carbon will self-organize in order to allow growth of the nano-elements. The nano-elements 707 may be aligned vertically or horizontally or even entangled. In the described example, the nano-elements 707 grow substantially vertically from the bottom of the box 705, towards its opening. By means of the different catalytic devices of nano-elements described earlier, it is also possible to grow nano-elements downwards if the box is dug in the base support 301 as this will be seen later on.

If the catalytic system 702 is an electric conductor, that there are several growth areas of nano-elements and that it is necessary to electrically dissociate different areas of the substrate 700, i.e. for example to avoid that all the growth areas of the nano-elements be at the same electric potential, it is possible to delimit areas by etching, with for example dry etching of the reactive plasma type, a trench 710 around the box 705, this trench 710 crossing right through the layer capable of receiving the electronic or electromechanical component 704, the barrier layer 703, the catalytic system 702 but only partly crossing the base support 301. Reference may be made to FIG. 6D. This trench 710 may then optionally be filled with an electrically insulating material (not shown) in order to mechanically strengthen the device.

Alternatively, it is possible to grow one or more nano-elements 709 substantially horizontally. The box 705 is etched from the layer capable of receiving the electronic or electromechanical component 704, but more deeply than in the previous example, so that its bottom locally exposes the base support 301 or is localized in the base support 301. The catalytic system 702 is transversely interrupted and it has a section 702a which is exposed and which contributes to forming the flanks of the box 705. The same applies for the barrier layer 703 and the layer capable of receiving the electronic or electromechanical component 704.

The result is illustrated in FIG. 6E. During another step illustrated in FIG. 6F, substantially horizontal growth of at least one nano-element 709 is effected from the exposed section 702a of the catalytic system 702. The nano-element 709 joins a flank of the box 705 to the other one. This configuration may be usable in applications of sensors or reconfigurable circuits.

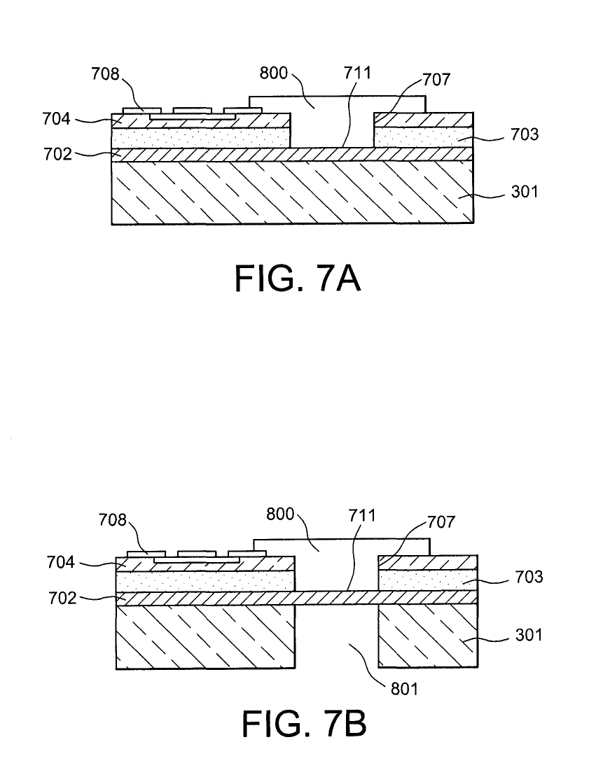

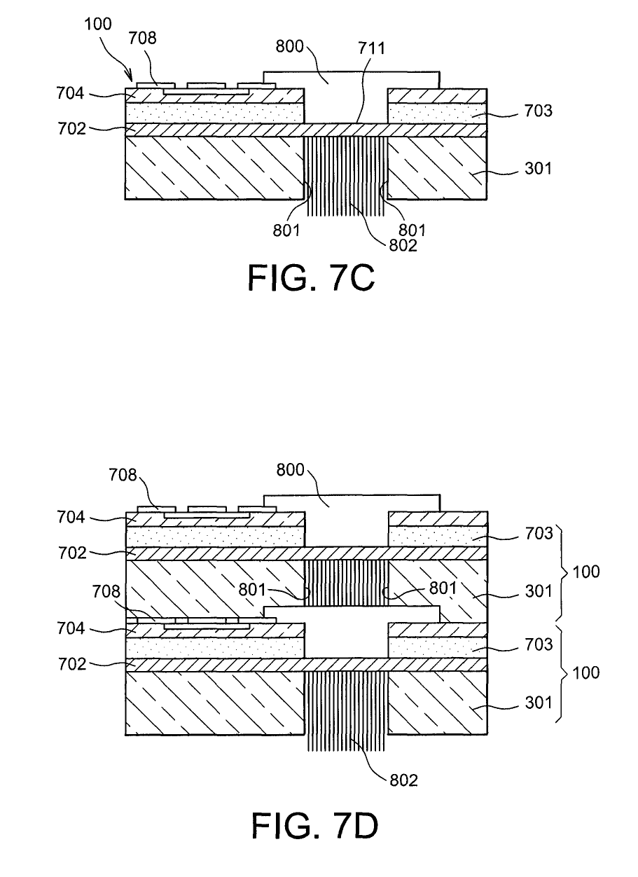

The present invention proposes a third method for making an electronic or electromechanical device according to the invention. One starts with a substrate 700 provided with at least one electronic or electromechanical component 708 and provided with at least one box as illustrated in FIG. 6B. The bottom of the box now referenced as 711, exposes the catalytic system 702. Instead of forming one or more nano-elements in the box 711, a contact device 800 providing electric contact, will be housed in the box 711. This contact device 800 may come into contact with the electronic component 708. In the case of FIG. 7A, there is a section having the shape of a T.

In FIG. 7B, a second box 801 is etched from the base support 301 and the bottom of which exposes the catalytic system 702. This is a box for nano-elements. The two boxes 711 and 801 are placed “back to back”, i.e. they are opposite through their bottoms but they may also be shifted sideways.

If the catalytic system 702 allows this, i.e. if it is notably compliant with one of the configurations of FIGS. 3B-3E, it is possible to effect growth downwards of one or more nano-elements 802 in the box 801. FIG. 7C illustrates such a structure with two boxes 711, 801 placed back to back, one receiving a contact device 800 and the other, and one or more nano-elements 802.

The structure 100 obtained in FIG. 7C instead of being used alone may be used with one or several others by stacking them.

In FIG. 7D, a stack is illustrated with two structures 100. They are assembled together by having the nano-elements 802 of a structure coincide with a contact device 800 of the other neighboring structure 100. Of course it would be possible to stack more than two structures on each other.

Of course, it is possible in the structure to invert the nano-elements and the contacts. The nano-elements may then be placed in an open box on the side of the electronic or electromechanical component and the contact in a box with which the base support is provided.

Although several embodiments of the present invention have been illustrated and described in detail, it will be understood that different changes and modifications may be made thereto without departing from the scope of the invention.

1-17. (canceled)

18. A substrate configured to support at least one electronic or electromechanical component and one or more nano-elements, comprising:
a base support;
a catalytic system for growing nano-elements comprising at least one catalytic layer, with a barrier layer, and with a layer configured to receive the electronic or electromechanical component,
wherein the catalytic system lies on the base support without any contact with the layer configured to receive the electronic or electromechanical component and the barrier layer is sandwiched between the catalytic system and the layer configured to receive the electronic or electromechanical component so as to avoid an interaction between the catalytic layer and the component, this barrier layer being without any contact with the base support, the layer configured to receive the electronic or electromechanical component, being in single-crystal Si or in Ge or in a mixture of these materials.

19. The substrate according to claim 18, wherein the catalytic system is formed with one or two groups of layers, each group including at least one catalytic layer.

20. The substrate according to claim 19, wherein at least one group of layers includes a protective layer on the catalytic layer and/or a supporting layer under the catalytic layer.

21. The substrate according to claim 20, wherein the catalytic system includes two groups of layers, and the supporting layer is common to both groups.

22. The substrate according to claim 18, wherein the catalytic system is formed with a catalytic layer sandwiched between two supporting layers, both supporting layers being sandwiched between two protective layers.

23. The substrate according to claim 19, wherein the catalytic layer is made on the basis of iron, nickel, cobalt, these elements being taken alone or as an alloy.

24. The substrate according to claim 19, wherein the protective layer and the supporting layer are made in a material selected from Al₂O₃, SiN, SiC, SiON, TiN, TiO₂, or TaN.

25. The substrate according to claim 18, wherein the base support and/or the barrier layer and/or the layer configured to receive the electronic or electromechanical component are multilayers.

26. An electronic or electromechanical device, comprising:
at least one structure comprising a substrate according to claim 18;
at least one electronic or electromechanical component positioned on or in the layer configured to receive the electronic or electromechanical component; and
at least one box dug in the substrate locally exposing the catalytic system on which one or more nano-elements are supported.

27. The electronic or electromechanical device according to claim 26, wherein the box includes flanks that transversely interrupt the barrier layer showing a section of the barrier layer that contributes to forming the flanks of the box.

28. The electronic or electromechanical device according to claim 26, wherein the locally exposed catalytic system forms a bottom of the box.

29. The electronic or electromechanical device according to claim 26, wherein the box includes flanks that transversely interrupt the catalytic system showing a section of the catalytic system that contributes to forming the flanks of the box, the locally exposed base support, forming a bottom of the box.

30. The electronic or electromechanical device according to claim 26, wherein the structure further comprises at least one contact device housed in another box dug in the substrate, the box of the nano-elements and the box of the contact device each having a bottom, the box of the nano-elements and the box of the contact device being opposite through their bottoms.

31. The electronic or electromechanical device according to claim 26, including plural structures stacked on each other.

32. A method for manufacturing a substrate according to claim 18, wherein
the catalytic system is formed on the base support;
the barrier layer is formed on the catalytic system;
the layer configured to receive the electronic or electromechanical component, in single-crystal Si or in Ge or in a mixture of both of these materials, is formed on the barrier layer without any contact with the catalytic system.

33. The manufacturing method according to claim 32, wherein the barrier layer and the layer configured to receive the electronic or electromechanical component are formed from:
a first adhesive bonding layer covering the base support itself covered with the catalytic system, the first adhesive bonding layer overlying the catalytic system or being a surface layer of the catalytic system, and
a second adhesive bonding layer covering an auxiliary semiconducting substrate, this auxiliary substrate having undergone ion implantation to embrittle it under the second adhesive bonding layer,
by assembling the base support and the auxiliary semiconducting substrate by molecular adhesion of their adhesive bonding layers, their assembled adhesive bonding layers providing the barrier layer,
and then by carrying out thermal fracture of the auxiliary semiconducting substrate at the ion implantation, a layer of the auxiliary semiconducting substrate remaining adhesively bonded to the barrier layer following this fracture providing the layer configured to receive the electronic or electromechanical component.

34. The manufacturing method according to claim 32, wherein the barrier layer and the layer configured to receive the electronic or electromechanical component are formed from:
a first adhesive bonding layer covering the base support itself covered with the catalytic system, the first adhesive bonding layer overlying the catalytic system or being a surface layer of the catalytic system, and
a second adhesive bonding layer covering a substrate of the SOI type, having an electrically insulated layer sandwiched between two semiconducting layers of different thicknesses, the second adhesive bonding layer covering the less thick semiconducting layer,
by assembling the base support and the substrate of the SOI type by molecular adhesion of their adhesive bonding layers, their assembled adhesive bonding layers providing the barrier layer,
and then by removing the thickest semiconducting layer and the electrically insulating layer of the substrate of the SOI type, the less thick semiconducting layer of the substrate of the SOI type providing the layer configured to receive the electronic or electromechanical component.
